(19) United States
(12) Patent Application Publication
(10) Pub. No.: US 2025/0081543 A1
(43) Pub. Date: Mar. 6, 2025

(54) Semiconductor Devices and Methods of Manufacturing Semiconductor Device

(71) Applicant: EPISIL TECHNOLOGIES INC., Hsinchu County (TW)

(72) Inventors: Yuan Liang LIU, Hsinchu County (TW); Yen Chang CHEN, Hsinchu County (TW); Yuan Chou CHANG, Hsinchu County (TW); Yi Chen LEE, Hsinchu County (TW)

(21) Appl. No.: 18/430,108

(22) Filed: Feb. 1, 2024

(30) Foreign Application Priority Data
Sep. 1, 2023 (TW) 112133190

(51) Int. Cl. H01L 29/06; H01L 29/16; H01L 29/66; H01L 29/78

(52) U.S. Cl. CPC H10D 62/106; H10D 12/031; H10D 30/65; H10D 62/8325

(57) ABSTRACT

A semiconductor device comprises: a silicon carbide epitaxial layer. The silicon carbide epitaxial layer has: a p-type buried layer; and a junction field effect region in contact with the p-type buried layer in a gate region. The semiconductor device further comprises: a gate oxide layer on the silicon carbide epitaxial layer; a poly silicon layer on the gate oxide layer; an interlayer dielectric layer on the poly silicon layer; a first recess formed in the silicon carbide epitaxial layer by passing through the interlayer dielectric layer, the poly silicon layer and the gate oxide layer in a source region; and a second recess formed in the poly silicon layer in the gate region, wherein a bottom surface of the second recess is higher than a top surface of the gate oxide layer.

### BACKGROUND OF THE INVENTION

### Field of the Invention

The present invention relates to a semiconductor device, in particular relates to a power metal oxide semiconductor transistor.

### Description of the Related Art

For traditional power metal oxide semiconductor transistors, the formation of a p-type buried layer requires additional photomasks, leading to an increase in costs. Additionally, the parasitic capacitance Cgd of traditional power metal oxide semiconductor transistors is relatively large, resulting in a poor switching speed of the transistor. Thus, there is a need for a new semiconductor device and a new method for manufacturing a semiconductor device to overcome the said problems.

### BRIEF SUMMARY OF THE INVENTION

In light of the previously described problems, the present disclosure provides a semiconductor device comprising a silicon carbide epitaxial layer having: a p-type buried layer; and a junction field effect region in contact with the p-type buried layer in a gate region. The semiconductor device further comprises: a gate oxide layer on the silicon carbide epitaxial layer; a poly silicon layer on the gate oxide layer; an interlayer dielectric layer on the poly silicon layer; a first recess formed in the silicon carbide epitaxial layer by passing through the interlayer dielectric layer, the poly silicon layer and the gate oxide layer in a source region; and a second recess formed in the poly silicon layer in the gate region, wherein a bottom surface of the second recess is higher than a top surface of the gate oxide layer.

The present disclosure also provides a method of manufacturing a semiconductor device comprising: sequentially depositing a first oxide film, a first poly silicon film and a second oxide film on a silicon carbide epitaxial layer; after definition of a p-type buried layer pattern, etching the second oxide film and the first poly silicon film and stopping etching at the first oxide film, and implanting a p-type buried layer into the silicon carbide epitaxial layer; depositing a second poly silicon film, etching back the second poly silicon film, and implanting a p-type well region over the p-type buried layer; sequentially depositing a third oxide film and a third poly silicon film, etching back the third poly silicon film, and implanting a heavily doped n-type region on a surface of the p-type well region; sequentially depositing a fourth oxide film and a fourth poly silicon film, etching back the fourth poly silicon film, and disposing a first heavily doped p-type region below the heavily doped n-type region and within the p-type well region; and removing the first oxide film, the first poly silicon film, the second oxide film, the second poly silicon film, the third oxide film, the third poly silicon film, the fourth oxide film and the fourth poly silicon film.

In summary, in the above-mentioned semiconductor device, since the bottom surface of the second recess in the gate region is higher than the top surface of the gate oxide layer, the dielectric layer between the gate and the drain becomes thicker. Furthermore, there is no overlap between the gate and the drain, so the parasitic capacitance Cgd between the gate and the drain becomes smaller, which can improve the switching speed. In addition, when manufacturing the semiconductor device, by using merely a photomask and multiple spacer self-alignments, the p-type buried layer, the p-type well region, the heavily doped n-type region and the heavily doped p-type region PP1 in the source region are defined from outer to inner without adding a photomask, so the cost does not increase.

### BRIEF DESCRIPTION OF THE DRAWINGS

FIG. 1 is a cross-sectional view of a semiconductor device 100 of the present disclosure.

FIG. 2 is a flow chart of a method 200 for manufacturing a semiconductor device of the present disclosure.

FIG. 3 is another cross-sectional view of the semiconductor device 100.

FIG. 4 is another cross-sectional view of the semiconductor device 100.

FIG. 5 is another cross-sectional view of the semiconductor device 100.

FIG. 6 is another cross-sectional view of the semiconductor device 100.

FIG. 7 is another cross-sectional view of the semiconductor device 100.

FIG. 8 is another cross-sectional view of the semiconductor device 100.

FIG. 9 is another cross-sectional view of the semiconductor device 100.

FIG. 10 is another cross-sectional view of the semiconductor device 100.

FIG. 11 is another cross-sectional view of the semiconductor device 100.

FIG. 12 is another cross-sectional view of the semiconductor device 100.

FIG. 13 is another cross-sectional view of the semiconductor device 100.

FIG. 14 is another cross-sectional view of the semiconductor device 100.

FIG. 15 is another cross-sectional view of the semiconductor device 100.

FIG. 16 is another cross-sectional view of the semiconductor device 100.

FIG. 17 is another cross-sectional view of the semiconductor device 100.

FIG. 18 is another flow chart of a method 200 for manufacturing a semiconductor device of the present disclosure.

FIG. 19 is another flow chart of a method 200 for manufacturing a semiconductor device of the present disclosure.

### DETAILED DESCRIPTION OF THE INVENTION

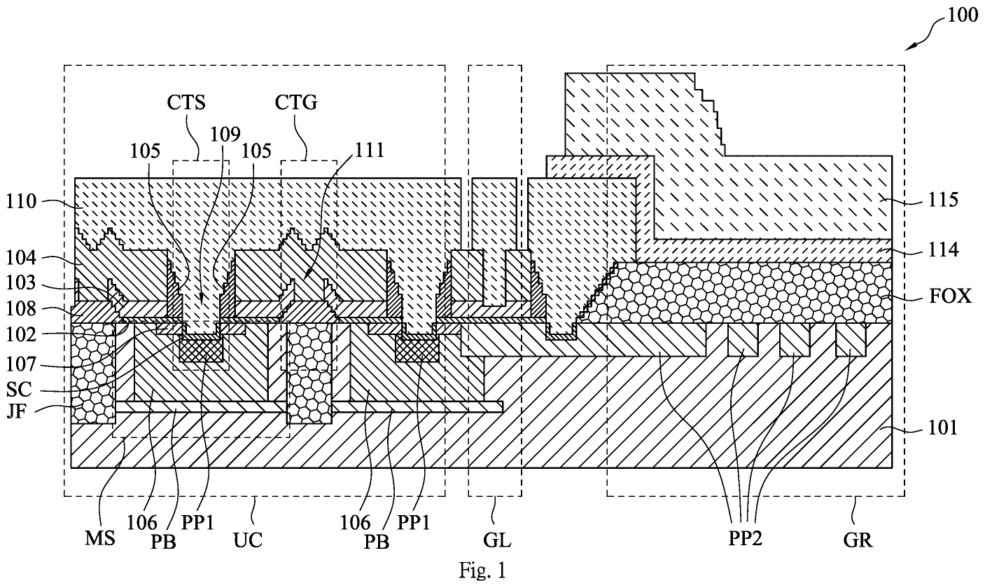

FIG. 1 is a cross-sectional view of a semiconductor device 100 of the present disclosure. As shown in FIG. 1, the semiconductor device 100 includes a unit cell region UC and a gate line region GL and a guard ring region GR outside the unit cell region UC. The semiconductor device 100 comprises: a silicon carbide epitaxial layer 101, a gate oxide layer 102, a poly silicon layer 103, an interlayer dielectric layer 104, a contact spacer 105, an island-shaped oxide layer 108 and a field oxide layer FOX, a passivation layer 114 and a polyimide layer 115 outside the unit cell region UC, wherein the silicon carbide epitaxial layer 101 has: a p-type well region 106, a heavily n-doped region 107, a silicide SC, a p-type buried layer PB, a junction field effect region JF, a heavily doped p-type region PP1 and a heavily doped p-type region PP2 outside the unit cell region UC.

In detail, in the silicon carbide epitaxial layer 101, the p-type well region 106 is over the p-type buried layer PB. The heavily doped p-type region PP1 is below the heavily doped n-type region 107 and within the p-type well region 106. The heavily doped n-type region 107 is on the surface of the p-type well region 106 and partially overlaps with the heavily doped p-type region PP1, wherein the depth of the heavily doped p-type region PP1 is greater than the depth of the heavily doped n-type region 107. The junction field effect region JF is in contact with the p-type buried layer PB in the gate region. The gate oxide layer 102 is on the silicon carbide epitaxial layer 101, wherein the gate oxide layer 102 overlaps with a portion of the heavily doped n-type region 107 and a portion of the p-type well region 106. The poly silicon layer 103 is on the gate oxide layer 102, and the poly silicon layer 103 can be formed as a gate of a transistor. The interlayer dielectric layer 104 is on the poly silicon layer 103. The contact spacer 105 is on the gate oxide layer 102 and in contact with the poly silicon layer 103 and the interlayer dielectric layer 104. The island-shaped oxide layer 108 is on the junction field effect region JF, wherein the thickness of the island-shaped oxide layer 108 is greater than the thickness of the gate oxide layer 102.

The semiconductor device 100 further comprises a first recess 109 and a second recess 111. The first recess 109 is formed in the silicon carbide epitaxial layer 101 by passing through the gate oxide layer 102, the poly silicon layer 103 and the interlayer dielectric layer 104 in the source region CTS. The second recess 111 is formed in the poly silicon layer 103 in the gate region CTG, wherein the bottom surface of the second recess 111 is the top surface of the island-shaped oxide layer 108, and the bottom surface of the second recess 111 higher than the top surface of the gate oxide layer 102. The dielectric layer between the gate and drain is thickened by the island-shaped oxide layer 108 in the gate region CTG. Furthermore, there is no overlap between the gate and the drain to make the parasitic capacitance Cgd smaller, which can improve the switching speed. On the other hand, the island-shaped oxide layer 108 can also reduce the tip electric field of the poly silicon layer 103 in the gate region CTG. The metal layer 110 can be used to form source contacts and gate contacts. The metal layer 110 is within the first recess 109 and in contact with the heavily doped p-type region PP1 and the heavily doped n-type region 107 through the silicide SC. The metal layer 110 is in contact with the poly silicon layer 103 (not shown) in the gate region CTG. The metal layer 110 is further disposed on the interlayer dielectric layer 104 and the contact spacer 105 and is in contact with the interlayer dielectric layer 104 and the contact spacer 105. In the gate region CTG, the interlayer dielectric layer 104 is further disposed within the second recess 111 so that the metal layer 110 is not in contact with the poly silicon layer 103 in the second recess 111. The heavily doped p-type region PP2 is located outside the unit cell region UC and in contact with the p-type well region 106.

In addition, at the backside of the silicon carbide epitaxial layer 101, the semiconductor device 100 further comprises a silicon carbide substrate (not shown) under the silicon carbide epitaxial layer 101 and a metal layer (not shown) under the silicon carbide substrate. The metal layer under the silicon carbide substrate can be used to form drain contacts. The composition of the metal layer 110 and the metal layer under the silicon carbide substrate can include Ni, Ti, TIN, AlCu, etc., but is not limited thereto. The field oxide layer FOX is disposed on the heavily doped p-type region PP2 outside the unit cell region UC. In some embodiments, a passivation layer 114 can be further disposed on the metal layer 110 and the field oxide layer FOX, and a polyimide layer 115 can further be disposed on the passivation layer 114.

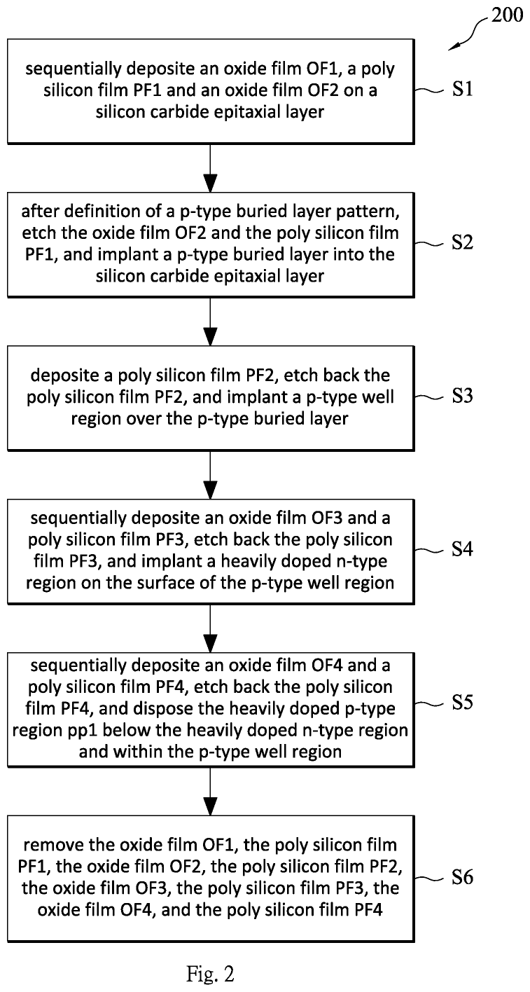

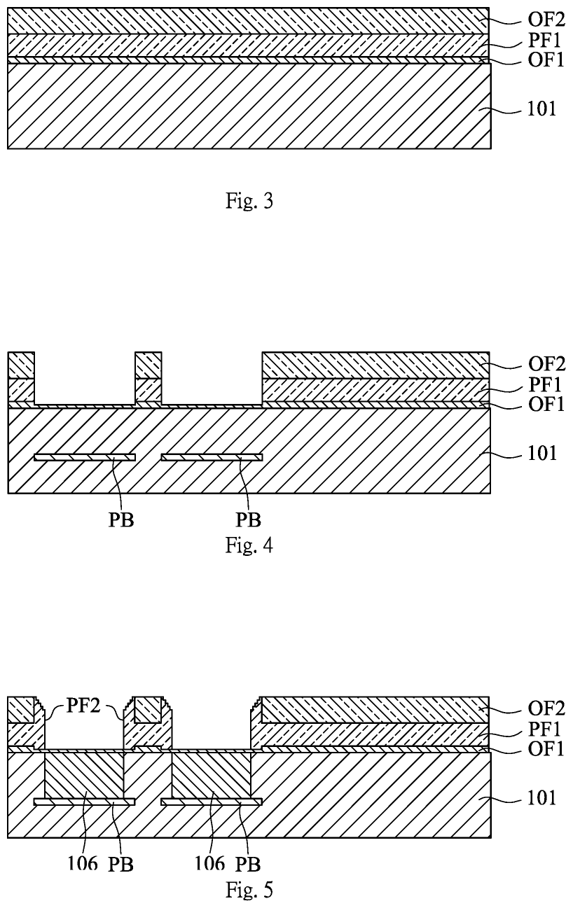

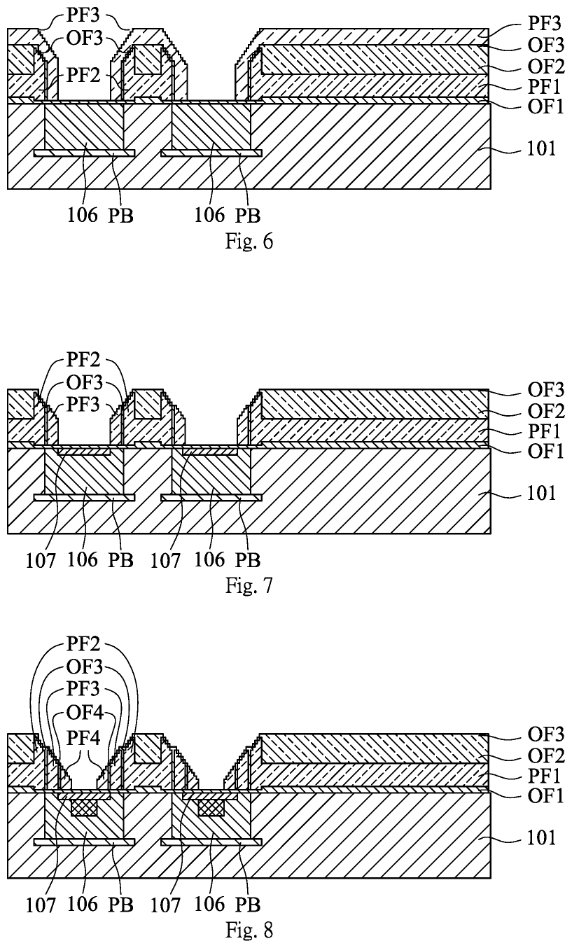

FIG. 2 is a flow chart of a method 200 of manufacturing a semiconductor device of the present disclosure, and FIGS. 3 to 8 are cross-sectional views of the semiconductor device 100 for illustrating steps S1-S6 of the method 200. First of all, in step S1, an oxide film OF1, a poly silicon film PF1 and an oxide film OF2 are sequentially deposited on the silicon carbide epitaxial layer 101, as shown in FIG. 3. In step S2, after definition of a p-type buried layer pattern, the oxide film OF2 and the poly silicon film PF1 are etched, the etching is stopped at the oxide film OF1, and the p-type buried layer PB is implanted into the silicon carbide epitaxial layer 101, as shown in FIG. 4. In step S3, the poly silicon film PF2 is deposited, the poly silicon film PF2 is etched back (the oxide film OF1 serves as an etching stop layer), and a p-type well region 106 is implanted over the p-type buried layer PB, as shown in FIG. 5. In step S4, the oxide film OF3 and the poly silicon film PF3 are sequentially deposited (as shown in FIG. 6), the poly silicon film PF3 is etched back (the oxide film OF3 serves as an etching stop layer), and the heavily doped n-type region 107 is implanted on the surface of the p-type well region 106, as shown in FIG. 7. In step S5, the oxide film OF4 and the poly silicon film PF4 are sequentially deposited, the poly silicon film PF4 is etched back (the oxide film OF4 serves as an etching stop layer), and the heavily doped p-type region PP1 is disposed below the heavily doped n-type region 107 and within the p-type well region 106, as shown in FIG. 8. In step S6, the oxide film OF1, the poly silicon film PF1, the oxide film OF2, the poly silicon film PF2, the oxide film OF3, the poly silicon film PF3, the oxide film OF4, and the poly silicon film PF4 are removed.

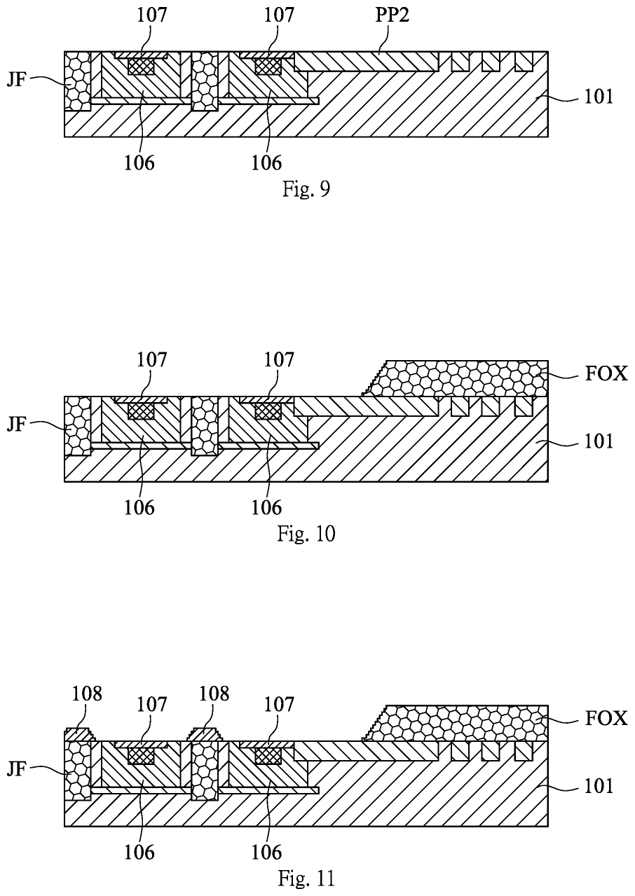

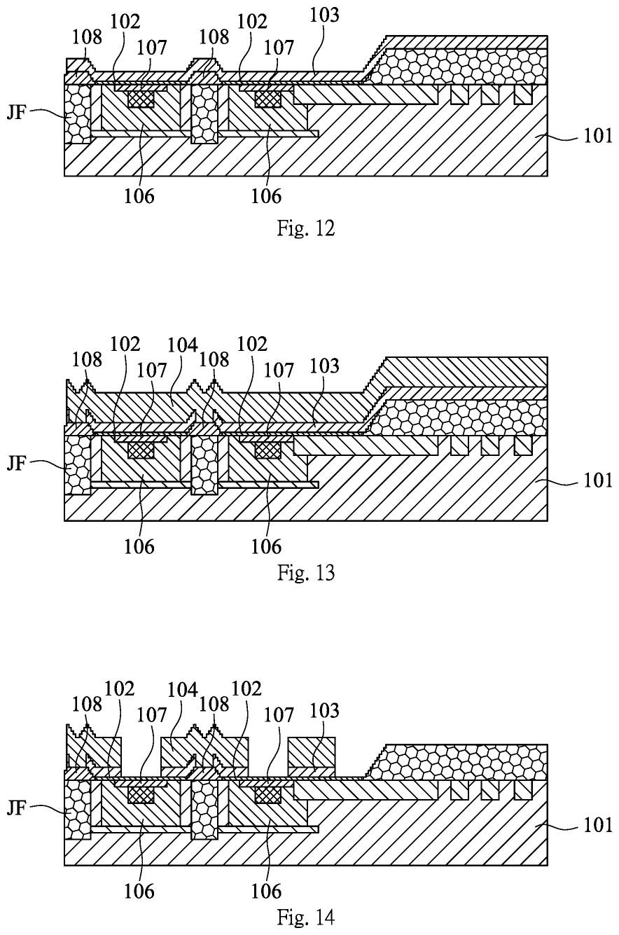

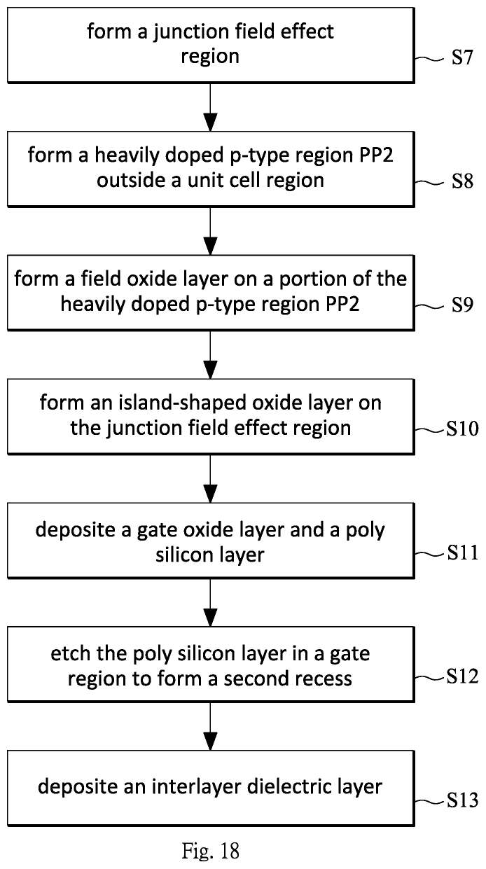

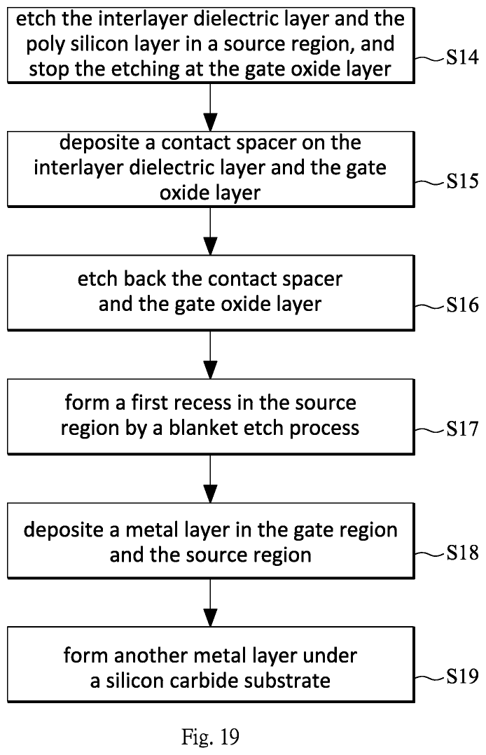

In addition, the method 200 further comprises steps S7 to S19, as shown in FIGS. 18 and 19. Please refer to FIG. 9. In step S7, the junction field effect region JF is formed. In step S8, the heavily doped p-type region PP2 is formed outside the unit cell region UC. As shown in FIG. 10, in step S9, the field oxide layer FOX is formed on a portion of the heavily doped p-type region PP2. As shown in FIG. 11, in step S10, the island-shaped oxide layer 108 is formed on the junction field effect region JF. As shown in FIG. 12, in step S11, the gate oxide layer 102 and the poly silicon layer 103 are deposited. In step S12, the poly silicon layer 103 in the gate region CTG is etched to form a second recess 111 and then to expose the island-shaped oxide layer 108. As shown in FIG. 13, in step S13, the interlayer dielectric layer 104 is deposited. As shown in FIG. 14, in step S14, the interlayer dielectric layer 104 and the poly silicon layer 103 in the source region CTS are etched, and the etching is stopped at the gate oxide layer 102.

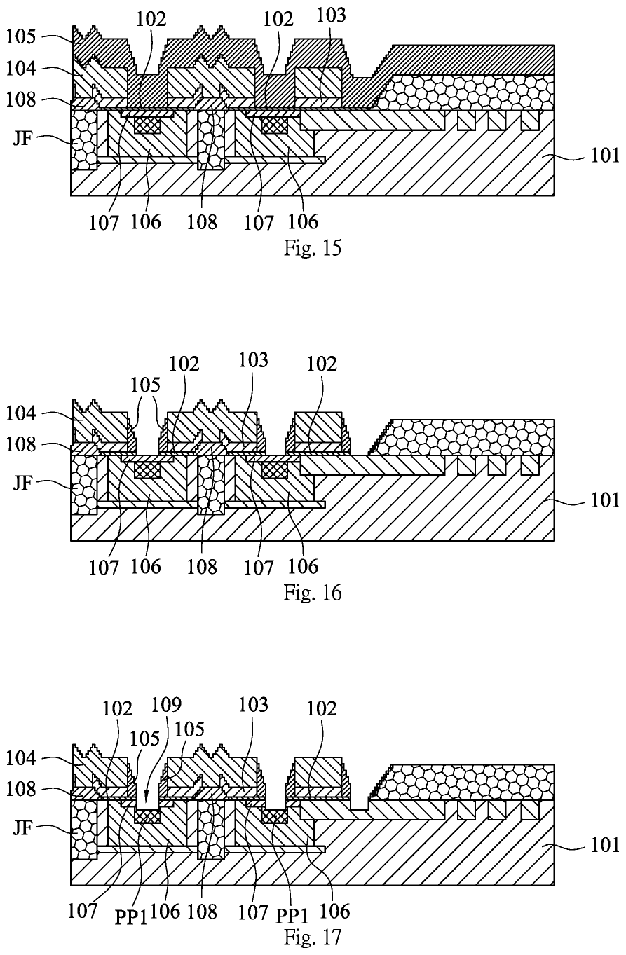

As shown in FIG. 15, in step S15, the contact spacer 105 is deposited on the interlayer dielectric layer 104 and the gate oxide layer 102. As shown in FIG. 16, in step S16, the contact spacer 105 and the gate oxide layer 102 are etched back to expose the interlayer dielectric layer 104 and the heavily doped n-type region 107. As shown in FIG. 17, in step S17, the first recess 109 is formed in the source region CTS by a blanket etch process to expose the heavily doped p-type region PP1. The depth of the first recess 109 exceeds the depth of the heavily doped n-type region 107. During the blanket etch process, the silicon carbide epitaxial layer 101 has a higher etch selectivity than the field oxide layer FOX, the interlayer dielectric layer 104 and the contact spacer 105. The method 200 further comprises step S18 of depositing a metal layer 110 in the gate region CTG and the source region CTS. Before depositing the metal layer 110, the silicide SC can also be formed on the heavily doped p-type region PP1 and the heavily doped n-type region 107, as shown in FIG. 1. The method 200 further comprises step S19 of forming another metal layer under the silicon carbide substrate under the silicon carbide epitaxial layer 101.

In the method 200, by using a photomask and multiple spacer (such as poly silicon films PF1 to PF4) self-alignments to define the p-type buried layer PB, the p-type well region 106, the heavily doped n-type layer 107 and the heavily doped p-type region PP1 from outer to inner. As shown in the region MS in FIG. 1, the region MS is where multiple spacers are created, and users can independently choose the conditions for the heavily doped p-type region PP1 without considering the conditions for heavily doped p-type region PP2 in the guard ring region GR. When implanting the heavily doped p-type region PP1, the method of the present disclosure can omit the concentration corresponding to low energy without affecting the concentration of the heavily doped n-type region 107. By omitting the concentration corresponding to low energy to implant the heavily doped p-type region PP1, the concentration of the heavily doped n-type region 107 can become higher to increase the contact area between the silicide SC and the heavily doped n-type region 107, thereby reducing the contact resistance.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A semiconductor device comprising:
a silicon carbide epitaxial layer having:
a p-type buried layer; and
a junction field effect region in contact with the p-type buried layer in a gate region;
a gate oxide layer on the silicon carbide epitaxial layer;
a poly silicon layer on the gate oxide layer;
an interlayer dielectric layer on the poly silicon layer;
a first recess formed in the silicon carbide epitaxial layer by passing through the interlayer dielectric layer, the poly silicon layer and the gate oxide layer in a source region; and
a second recess formed in the poly silicon layer in the gate region, wherein a bottom surface of the second recess is higher than a top surface of the gate oxide layer.

2. The semiconductor device of claim 1, wherein the silicon carbide epitaxial layer further having:
a p-type well region above the p-type buried layer;
a heavily doped n-type region on a surface of the p-type well region; and
a first heavily doped p-type region below the heavily doped n-type region and within the p-type well region,
wherein a depth of the first recess exceeds a depth of the heavily doped n-type region.

3. The semiconductor device of claim 1, further comprising:
a contact spacer on the gate oxide layer and in contact with the interlayer dielectric layer and the poly silicon layer; and
an island-shaped oxide layer on the junction field effect region, wherein a thickness of the island-shaped oxide layer is greater than a thickness of the gate oxide layer.

4. The semiconductor device of claim 2, further comprising:
a first metal layer within the first recess and in contact with the first heavily doped p-type region and the heavily doped n-type region through silicide.

5. The semiconductor device of claim 4, wherein the first metal layer is further disposed on the interlayer dielectric layer and the contact spacer and in contact with the interlayer dielectric layer and the contact spacer.

6. The semiconductor device of claim 4, wherein the interlayer dielectric layer is further disposed within the second recess, and the first metal layer within the second recess is not in contact with the poly silicon layer.

7. The semiconductor device of claim 1, further comprising:
a silicon carbide substrate under the silicon carbide epitaxial layer; and
a second metal layer under the silicon carbide substrate.

8. A method for manufacturing a semiconductor device comprising:
sequentially depositing a first oxide film, a first poly silicon film and a second oxide film on a silicon carbide epitaxial layer;
after definition of a p-type buried layer pattern, etching the second oxide film and the first poly silicon film and stopping etching at the first oxide film, and implanting a p-type buried layer into the silicon carbide epitaxial layer;
depositing a second poly silicon film, etching back the second poly silicon film, and implanting a p-type well region over the p-type buried layer;
sequentially depositing a third oxide film and a third poly silicon film, etching back the third poly silicon film, and implanting a heavily doped n-type region on a surface of the p-type well region;
sequentially depositing a fourth oxide film and a fourth poly silicon film, etching back the fourth poly silicon film, and disposing a first heavily doped p-type region below the heavily doped n-type region and within the p-type well region; and
removing the first oxide film, the first poly silicon film, the second oxide film, the second poly silicon film, the third oxide film, the third poly silicon film, the fourth oxide film and the fourth poly silicon film.

9. The method of claim 8, further comprising:
forming a junction field effect region;
forming a second heavily doped p-type region outside a unit cell;
forming a field oxide layer on a portion of the second heavily doped p-type region;
forming an island-shaped oxide layer on the junction field effect region;
depositing a gate oxide layer and a poly silicon layer;
in a gate region, etching the first poly silicon layer to expose the island-shaped oxide layer; and
depositing an interlayer dielectric layer.

10. The method of claim 9, further comprising:
etching the interlayer dielectric layer and the first poly silicon layer and stopping etching at the gate oxide layer;
depositing a contact spacer on the interlayer dielectric layer and the gate oxide layer;
etching back the contact spacer and the gate oxide layer to expose the interlayer dielectric layer and the heavily doped n-type region; and
by a blanket etch process, forming a first recess in a source region to expose the first heavily doped p-type region, wherein a depth of the first recess exceeds a depth of the heavily doped n-type region.

11. The method of claim 10, further comprising:
depositing a first metal layer in the gate region and the source region.

12. The method of claim 10, wherein during the blanket etch process, the silicon carbide epitaxial layer has a higher etch selectivity than the field oxide layer, the interlayer dielectric layer and the contact spacer.

13. The method of claim 8, further comprising:
forming a second metal layer under a silicon carbide substrate under the silicon carbide epitaxial layer.
